(19) United States
(12) Patent Application Publication
(10) Pub. No.: US 2012/0171863 A1
(43) Pub. Date: Jul. 5, 2012

(54) METAL SILICIDE FILM FORMING METHOD

(75) Inventors: Mikio Suzuki, Nirasaki-shi (JP); Takashi Nishimori, Nirasaki-shi (JP); Hideki Yuasa, Nirasaki-shi (JP)

(73) Assignee: TOKYO ELECTRON LIMITED, Tokyo (JP)

(21) Appl. No.: 13/415,935

(22) Filed: Mar. 9, 2012

Related U.S. Application Data
(63) Continuation of application No. PCT/JP2010/064071, filed on Aug. 20, 2010.

(30) Foreign Application Priority Data
Sep. 15, 2009 (JP) 2009-213290

(51) Int. Cl. H01L 21/285

(52) U.S. Cl. 438/664; 257/E21.165

(57) ABSTRACT

There is provided a metal silicide film forming method that includes providing a substrate having thereon a silicon part (process 1); forming a metal film on a surface of the silicon part of the substrate by a CVD process using a nitrogen-containing metal compound as a film forming source material (process 2); performing an annealing process on the substrate under a hydrogen gas atmosphere; and forming a metal silicide by a reaction between the metal film and the silicon part (process 3). Here, the nitrogen-containing metal compound as the film forming source material is metal amidinate. Further, the metal film is a nickel (Ni) film. Furthermore, the metal amidinate is nickel amidinate.

### CROSS-REFERENCE TO RELATED APPLICATION

This application is a Continuation of International Application No. PCT/JP2010/064071 filed on Aug. 20, 2010, which claims the benefit of Japanese Patent Application No. 2009-213290 filed on Sep. 15, 2009. The entire disclosure of the prior application is incorporated herein by reference in its entirety.

### FIELD OF THE INVENTION

The present disclosure relates to a metal silicide film forming method of forming a metal silicide film by an annealing process after forming a metal film by a chemical vapor deposition (CVD) process.

### BACKGROUND OF THE INVENTION

Recently, semiconductor devices need to be have a high-speed operation and low power consumption. For example, in order to realize low resistance of a source and drain contact or a gate electrode of a metal-oxide-semiconductor (MOS), a silicide is formed by a salicide process. As the silicide, attention is given to a nickel silicide (NiSi) capable of consuming a small amount of silicon and having low resistance.

There has been widely used a method of forming a nickel (Ni) film on a silicon (Si) substrate or a polysilicon film by a physical vapor deposition (PVD) process such as a sputtering process, and then, forming a NiSi film by an annealing process under an inert gas atmosphere (see, for example, Japanese Patent Laid-open Publication No. H09-153616).

However, the PVD process has poor step coverage. For this reason, along with miniaturization of semiconductor devices, the Ni film needs to be formed by a CVD process having better step coverage (see, for example, International Publication No. WO 2007/116982).

As a film forming source material (precursor) used for forming the Ni film by the CVD process, there has been used a nitrogen (N)-containing organic metal material such as nickel amidinate. However, when the Ni film is formed by using the N-containing precursor, since N (nitrogen) is introduced into the film, nickel nitride (NiₓN) is formed during the Ni film forming process. As a result, even when the annealing process is performed, the silicide is not easily formed. Accordingly, after forming the Ni film by the PVD process or after forming the Ni film by means of the CVD process by using a source material without containing N, e.g., Ni(PF₃)₄, the silicide is formed by the annealing process for tens of seconds. However, when the Ni film is formed by using the N-containing precursor, the annealing process for tens of minutes needs to be performed.

This problem is also generated when other metal silicides are formed by using the N-containing compound.

### BRIEF SUMMARY OF THE INVENTION

In an illustrative embodiment, there is provided a metal silicide film forming method capable of forming a metal silicide film in a short time by annealing a metal film formed by using a nitrogen-containing metal compound as a film forming source material and then reacting the metal film with a underlying silicon part.

In accordance with one aspect of an illustrative embodiment, there is provided a metal silicide film forming method that includes providing a substrate having thereon a silicon part; forming a metal film on a surface of the silicon part of the substrate by a CVD process using a nitrogen-containing metal compound as a film forming source material, the metal film being composed of a metal contained in the nitrogen-containing metal compound; performing an annealing process on the substrate under a hydrogen gas atmosphere; and forming a metal silicide by a reaction between the metal film and the silicon part. Here, the nitrogen-containing metal compound as the film forming source material may be metal amidinate. Further, the metal film may be a nickel (Ni) film. Furthermore, the metal amidinate may be nickel amidinate.

In accordance with another aspect of an illustrative embodiment, there is provided a storage medium having stored thereon computer-executable instructions that, in response to execution, cause a metal silicide film forming apparatus to perform a metal silicide film forming method. The metal silicide film forming method includes providing a substrate having thereon a silicon part; forming a metal film on a surface of the silicon part of the substrate by a CVD process using a nitrogen-containing metal compound as a film forming source material, the metal film being composed of a metal contained in the nitrogen-containing metal compound; performing an annealing process on the substrate under a hydrogen gas atmosphere; and forming a metal silicide by a reaction between the metal film and the silicon part. Here, the nitrogen-containing metal compound as the film forming source material may be metal amidinate. Further, the metal film may be a nickel (Ni) film. Furthermore, the metal amidinate may be nickel amidinate.

### BRIEF DESCRIPTION OF THE DRAWINGS

Non-limiting and non-exhaustive embodiments will be described in conjunction with the accompanying drawings. Understanding that these drawings depict only several embodiments in accordance with the disclosure and are, therefore, not to be intended to limit its scope, the disclosure will be described with specificity and detail through use of the accompanying drawings, in which:

FIG. 1 is a flowchart showing a silicide film forming method in accordance with an illustrative embodiment;

FIG. 2 is a schematic diagram showing an example of a silicide film forming apparatus for performing the silicide film forming method in accordance with the illustrative embodiment;

FIG. 3 is a cross-sectional view showing a film forming unit provided in the silicide film forming apparatus of FIG. 2;

FIG. 4 is a cross-sectional view showing an annealing processing unit provided in the silicide film forming apparatus of FIG. 2;

FIG. 5 is a diagram showing a film thickness, resistivity and an X-ray diffraction (XRD) measurement result of a Ni film formed on a SiO₂ wafer by using Ni(II)(tBu-AMD)₂ as a film forming source material;

FIG. 6A shows an X-ray diffraction (XRD) measurement result and resistivity of a film after forming a Ni film on the SiO₂ wafer by using the Ni(II)(tBu-AMD)₂ as the film forming source material and then performing an NH₃ annealing process;

FIG. 6B shows an X-ray diffraction (XRD) measurement result and resistivity of a film after forming a Ni film on the SiO₂ wafer by using the Ni(II)(tBu-AMD)₂ as the film forming source material and then performing a H₂ annealing process;

FIG. 7A shows an X-ray diffraction (XRD) measurement result and resistivity of a film after forming a Ni film on the Si wafer by using the Ni(II)(tBu-AMD)₂ as the film forming source material and then performing the NH₃ annealing process;

FIG. 7B shows an X-ray diffraction (XRD) measurement result and resistivity of a film after forming a Ni film on the Si wafer by using the Ni(II)(tBu-AMD)₂ as the film forming source material and then performing the H₂ annealing process;

FIG. 8A shows an X-ray diffraction (XRD) measurement result of a film after forming a Ni film on the Si wafer by using the Ni(II)(tBu-AMD)₂ as the film forming source material and then respectively performing the H₂ annealing process, the NH₃ annealing process and an Ar annealing process at about 450° C.;

FIG. 8B shows an X-ray diffraction (XRD) measurement result of a film after forming a Ni film on the Si wafer by using the Ni(II)(tBu-AMD)₂ as the film forming source material and then respectively performing the H₂ annealing process, the NH₃ annealing process and the Ar annealing process at about 500° C.;

FIG. 8C shows an X-ray diffraction (XRD) measurement result of a film after forming a Ni film on the Si wafer by using the Ni(II)(tBu-AMD)₂ as the film forming source material and then respectively performing the H₂ annealing process, the NH₃ annealing process and the Ar annealing process at about 550° C.;

FIG. 9 shows SEM photographs of a cross-section of a film after forming a Ni film on the Si wafer by using the Ni(II)(tBu-AMD)₂ as the film forming source material and then respectively performing the H₂ annealing process, the NH₃ annealing process and the Ar annealing process at about 450° C., about 500° C., and about 550° C.;

FIG. 10 shows SEM photographs of a film surface after forming a Ni film on the Si wafer by using the Ni(II)(tBu-AMD)₂ as the film forming source material and then respectively performing the H₂ annealing process, the NH₃ annealing process and the Ar annealing process at about 450° C., about 500° C., and about 550° C.;

FIG. 11 shows a relationship between an annealing temperature and resistivity after forming a Ni film on the Si wafer by using the Ni(II)(tBu-AMD)₂ as the film forming source material and then respectively performing the H₂ annealing process, the NH₃ annealing process and the Ar annealing process;

FIG. 12 shows a table for an annealing gas, an annealing temperature, a resistance value, and a film thickness and resistivity obtained from SEM photographs;

FIG. 13A shows an XPS analysis measurement result of a Ni film in a deposition state;

FIG. 13B shows an XPS analysis result for the Ni film after the H₂ annealing process at about 450° C.;

FIG. 13C shows a XPS analysis result for the Ni film after the Ar annealing process at about 450° C.;

FIG. 14A shows an XPS analysis results for the Ni film in the deposition state;

FIG. 14B shows an XPS analysis result for the Ni film after the H₂ annealing process at 550° C.; and

FIG. 14C shows an XPS analysis result for the Ni film after the Ar annealing process at about 550° C.

### DETAILED DESCRIPTION OF THE INVENTION

Hereinafter, an illustrative embodiment will be described with reference to the accompanying drawings.

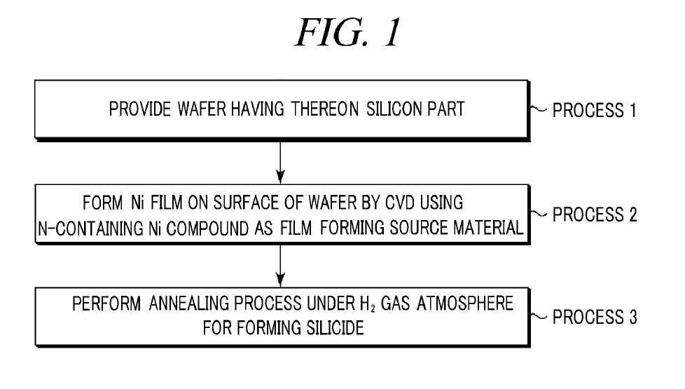

In the illustrative embodiment, there will be described a case where a nickel silicide is formed as a metal silicide. FIG. 1 is a flowchart showing a metal silicide film forming method in accordance with the illustrative embodiment.

As shown in FIG. 1, a semiconductor wafer (hereinafter, referred to as simply a “wafer”) having thereon a silicon part is prepared (process 1). By way of example, when a nickel silicide film is formed on a source or a drain, the silicon part may be a silicon substrate. Meanwhile, when a nickel silicide is formed as a gate electrode, the silicon part may be a polysilicon film.

Subsequently, a Ni film is formed on the surface of the wafer by means of a CVD process by using a nitrogen (N)-containing Ni compound as a film forming source material (precursor) (process 2). As the N-containing Ni compound serving as the film forming source material, nickel amidinate may be used. As the nickel amidinate, Ni(II)N, N′-ditertiary butylamidinate (Ni(II)(tBu-AMD)₂), Ni(II)N, N′-diisopropyl amidinate (Ni(II)(iPr-AMD)₂), Ni(II)N, N′-diethyl amidinate (Ni(II)(Et-AMD)₂), or Ni(II)N, N′-dimethyl amidinate (Ni(II)(Me-AMD)₂) may be used.

In order to form the Ni film by means of the CVD process by using the nickel amidinate as the film forming source material, a NH₃ gas or a gas mixture of a NH₃ gas and a H₂ gas is supplied as a reduction gas together with the film forming source material. Then, the wafer is heated to a certain temperature, desirably, about 120° C. to about 280° C. In this way, the Ni film is formed by a reaction on the surface of the wafer. In this case, the CVD process may be a thermal CVD process or a plasma CVD process. Since the N-containing Ni compound is used as the film forming source material, N (nitrogen) included in the film forming source material remains in the Ni film, so that nickel nitride (NiₓN) is generated.

After forming the Ni film, an annealing process is performed on the wafer under a hydrogen gas (H₂ gas) atmosphere in order to form the silicide (process 3). In this way, since the annealing process is performed under the H₂ gas atmosphere, the N or other impurities in the Ni film are rapidly removed by H (hydrogen) introduced into the Ni film, and the reaction between Si of the silicon part of the wafer and Ni of the Ni film thereon is accelerated. Accordingly, a nickel silicide (NiSi) film can be rapidly formed. Here, desirably, the annealing process under the H₂ gas atmosphere may be performed in a temperature range of from about 450° C. to about 550° C.

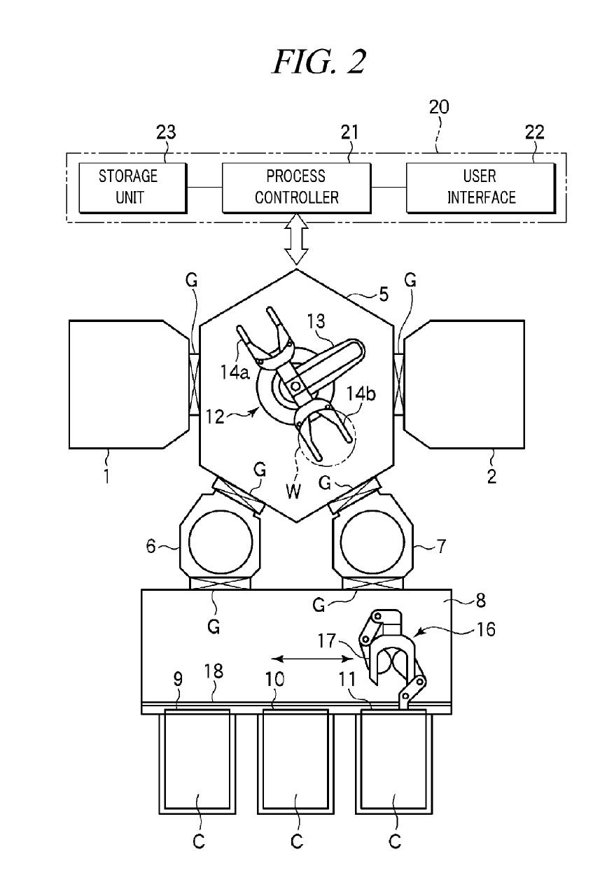

An example of an apparatus for performing the nickel silicide film forming method in accordance with the illustrative embodiment will be described. FIG. 2 is a schematic view showing an example of a silicide film forming apparatus for performing the metal silicide film forming method in accordance with the illustrative embodiment. This silicide film forming apparatus is a multi chamber type apparatus capable of consecutively performing the CVD-Ni film forming process and the annealing process under the hydrogen gas atmosphere in-situ while maintaining a vacuum state.

This silicide film forming apparatus includes a film forming unit 1 and an annealing processing unit 2, and the units 1 and 2 are maintained in a vacuum state. Further, the units 1 and 2 are connected to a transfer chamber 5 maintained in a vacuum state via gate valves G. Load-lock chambers 6 and 7 are connected to the transfer chamber 5 via gate valves G. A loading/unloading chamber 8 under an atmospheric atmosphere is connected to sides of the load-lock chambers 6 and 7 opposite to the sides of the load-lock chambers 6 and 7 connected to the transfer chamber 5. Three carrier ports 9, 10 and 11 are provided at a side of the loading/unloading chamber 8 opposite to a side of the loading/unloading chamber 8 connected to the load-lock chambers 6 and 7. Carriers C for containing therein wafers W are mounted on the carrier ports 9, 10 and 11.

A transfer device 12 is provided in the transfer chamber 5 to load and unload the wafer W into and from the film forming unit 1, the annealing processing unit 2, and the load-lock chambers 6 and 7. The transfer device 12 is positioned in a substantially center of the transfer chamber 5. Further, the transfer device 12 has a rotation/extension member 13 configured to rotatable and extensible/contractible; and two support arms 14a and 14b for supporting thereon the semiconductor wafer W at a front end of the rotation/extension member 13. The two support arms 14a and 14b are connected to the rotation/extension member 13 so as to face the opposite directions.

A transfer device 16 is provided in the loading/unloading chamber 8 to load and unload of the wafer W into and from the carriers C and the load-lock chambers 6 and 7. The transfer device 16 has a multi-joint arm and is configured to move on a rail 18 along an arrangement of the carriers C. The transfer device 16 mounts the wafer W on a support arm 17 provided on the front end thereof, and transfers the wafer W.

The silicide film forming apparatus has a controller for controlling each unit of the silicide film forming apparatus. The controller 20 includes a process controller 21 having a micro processor (computer), a user interface 22, and a storage unit 23. The process controller 21 is electrically connected to each unit of the silicide film forming apparatus, and each unit is controlled by the process controller 21. The user interface 22 is connected to the process controller 21 and includes a key board for allowing an operator to input a command to manage each unit of the silicide film forming apparatus or a display for visualizing and displaying an operation status of each unit of the silicide film forming apparatus. The storage unit 23 is also connected to the process controller 21. The storage unit 23 stores therein control programs for implementing various processes to be performed by the silicide film forming apparatus under the control of the process controller 21 or a control program for performing a preset process in each unit of the silicide film forming apparatus according to processing conditions, i.e., process recipes; or various databases. The process recipes are stored in a storage medium (not illustrated) in the storage unit 23. The storage medium may be a hard disk, or may be a portable device such as a CD-ROM, a DVD or a flash memory. Otherwise, the recipes may be received appropriately from another apparatus via, for example, a dedicate line.

If necessary, a certain process recipe is read out from the storage unit 23 in response to an instruction from the user interface 22 and a process according to the retrieved process recipe is executed by the process controller 21, so that a desired process is performed by the silicide film forming apparatus under the control of the process controller 21.

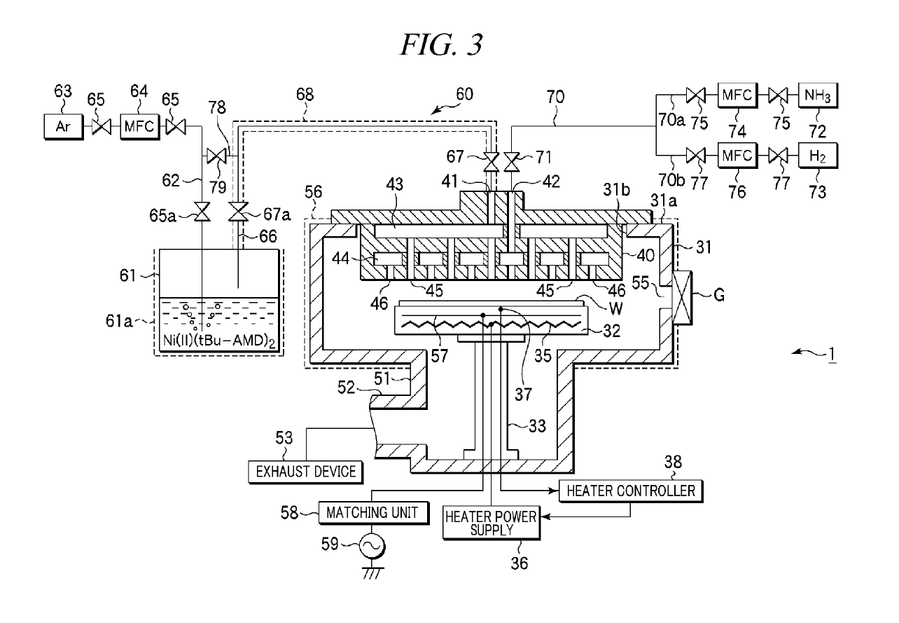

As shown in the schematic cross-sectional view of FIG. 3, the film forming unit 1 has a substantially cylindrical chamber 31 and the inside of the chamber 31 is kept airtight. In the chamber 31, there is provided a susceptor 32 for horizontally supporting thereon the wafer W as a target substrate. The susceptor 32 is supported by a cylindrical supporting member 33 extending from a bottom portion of an exhaust room to be described later to a central lower portion of the susceptor 32. The susceptor 32 is made of ceramic such as AlN. A heater 35 is embedded in the susceptor 32. A heater power supply 36 is connected to the heater 35. A thermocouple 37 is embedded in a portion close to a top surface of the susceptor 32. A signal of the thermocouple 37 is transmitted to a heater controller 38. The heater controller 38 transmits an instruction to the heater power supply 36 in response to the signal of the thermocouple 37, and the wafer W is controlled to have a certain temperature by the heater 35. An electrode 57 for applying a high frequency power is embedded in a portion above the heater 35 within the susceptor 32. A high frequency power supply 59 is connected to the electrode 57 via a matching unit 58. If necessary, by applying a high frequency power to the electrode 57, plasma is generated, so that the plasma CVD process is performed. Three wafer lift pins (not illustrated) are provided in the susceptor 32 so as to be protruded from and retracted into the surface of the susceptor 32. When transferring the wafer W, the wafer lift pins are protruded from the surface of the susceptor 32.

A circular hole 31b is formed at a ceiling wall of the chamber 31. A shower head 40 is inserted into the circular hole 31b so as to be protruded toward the inside of the chamber 31. The shower head 40 is configured to discharge a film forming gas supplied into the chamber 31 from a gas supply unit 60 to be described later. A first inlet 41 and a second inlet 42 are formed at a top portion of the shower head 40. The N-containing Ni compound, e.g., nickel amidinate such as Ni(II)N, N′-ditertiary butylamidinate (Ni(II)(tBu-AMD)₂) as the film forming source gas is introduced into the chamber 31 through the first inlet 41. Further, an NH₃ gas or a gas mixture of an NH₃ gas and a H₂ gas is introduced into the chamber 31 through the second inlet 42 as a reduction gas.

An upper space 43 and a lower space 44 are formed in the shower head 40. The first inlet 41 is connected to the upper space 43, and a first gas discharge path 45 extends from the upper space 43 to a bottom surface of the shower head 40. The second inlet 42 is connected to the lower space 44, and a second gas discharge path 46 extends from the lower space 44 to the bottom surface of the shower head 40. That is, the shower head 40 is configured to respectively discharge the Ni compound gas as the film forming source material and the reduction gas through the discharge paths 45 and 46, independently.

An exhaust room 51 is provided at a bottom wall of the chamber 31 so as to be protruded downwardly. An exhaust line 52 is connected to a sidewall of the exhaust room 51, and an exhaust device 53 having a vacuum pump or a pressure control valve is connected to the exhaust line 52. By operating the exhaust device 53, the inside of the chamber 31 can be depressurized in a certain pressure level.

A loading/unloading port 55 and a gate valve G are provided at a sidewall of the chamber 31. The wafer W is transferred between the transfer chamber 5 and the chamber 31 through the loading/unloading port 55. The gate valve G is configured to open and close the loading/unloading port 55. A heater 56 is provided at a wall of the chamber 31, and a temperature of an inner wall of the chamber 31 can be controlled during the film forming process.

The gas supply unit 60 has a film forming source material tank 61 for storing therein the N-containing Ni compound, e.g., the nickel amidinate such as Ni(II)N, N′-ditertiary butylamidinate (Ni(II)(tBu-AMD)₂) as the film forming source material. A heater 61a is provided at a periphery of the film forming source material tank 61, and the film forming source material in the film forming source material tank 61 can be heated to have a certain temperature by the heater 61a.

In order to supply an Ar gas as a bubbling gas into the film forming source material tank 61 from the above, a bubbling line 62 is inserted into the film forming source material tank 61 and immersed in the film forming source material. An Ar gas supply source 63 is connected to the bubbling line 62. A mass flow controller 64 as a flow rate controller and valves 65 positioned at upstream and downstream sides of the mass flow controller 64 are provided at the bubbling line 62. One end of a source gas discharge line 66 is inserted into the film forming source material tank 61 from the above of the film forming source material tank 61. The other end of the source gas discharge line 66 is connected to the first inlet 41 of the shower head 40. A valve 67 is provided at the source gas discharge line 66. Further, a heater 68 is provided at the source gas discharge line 66 to prevent condensation of a film forming source gas. By supplying the Ar gas as the bubbling gas into the film forming source material, the film forming source material within the film forming source material tank 61 is vaporized by the bubbling gas. The vaporized film forming source gas is supplied into the shower head 40 through the source gas discharge line 66 and the first inlet 41.

The bubbling line 62 and the source gas discharge line 66 are connected to each other by a by-pass line 78. A valve 79 is provided at the by-pass line 78. Valve 65a is provided at the bubbling line 62 downward from a connecting position between the bubbling line 62 and the by-pass line 78. Further, valve 67a is provided at source gas discharge line 66 downward from a connecting position between the source gas discharge line 66 and the by-pass line 78. By closing the valves 65a and 67a and opening the valve 79, the argon gas as a purge gas can be supplied from the Ar gas supply source 63 into the chamber 31 through the bubbling line 62, the by-pass line 78 and the source gas discharge line 66.

A reduction gas supply line 70 is connected to the second inlet 42 of the shower head 40 so as to supply the reduction gas. A valve 71 is provided at the reduction gas supply line 70. The reduction gas supply line 70 is branched into branch lines 70a and 70b. An NH₃ gas supply source 72 is connected to the branch line 70a. A H₂ gas supply source 73 is connected to the branch line 70b. Further, a mass flow controller 74 as a flow rate controller and valves 75 positioned at upstream and downstream sides of the mass flow controller 74 are provided at the branch line 70a. A mass flow controller 76 as a flow rate controller and valves 77 positioned at upstream and downstream sides of the mass flow controller 76 are provided at the branch line 70b. If the plasma CVD process is performed by applying the high frequency power to the electrode 57, although not illustrated, the reduction gas supply line 70 may further include an additional branch line, and the additional branch line may be connected to an Ar gas supply source for plasma ignition. Here, a mass flow controller and valves positioned at upstream and downstream sides of the mass flow controller may be provided at the additional branch line.

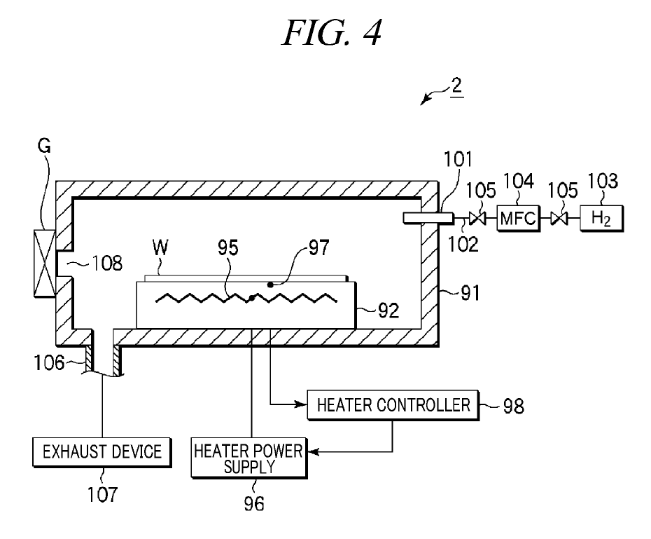

As shown in the schematic cross-sectional view of FIG. 4, the annealing processing unit 2 has a substantially cylindrical chamber 91 and the inside of the chamber 91 is kept airtight. At a bottom portion in the chamber 91, there is provided a susceptor 92 for horizontally supporting thereon the wafer W as the target substrate. The susceptor 92 is made of ceramic such as AlN. A heater 95 is embedded in the susceptor 92. A heater power supply 96 is connected to the heater 95. A thermocouple 97 is embedded in a portion close to a top surface of the susceptor 92. A signal of the thermocouple 97 is transmitted to a heater controller 98. In response to a signal of the thermocouple 97, the heater controller 98 transmits an instruction to the heater power supply 96, and the wafer W is controlled to have a certain temperature by the heater 95. Three wafer lift pins (not illustrated) are provided in the susceptor so as to be protruded from and retracted into the surface of the susceptor 92. When transferring the wafer W, the wafer lift pins are protruded from the surface of the susceptor 92.

A gas inlet 101 is provided at an upper portion of a sidewall of the chamber 91, and a H₂ gas supply source 103 is connected to the gas inlet 101 via a line 102. A mass flow controller 104 as the flow rate controller and valves 105 positioned at upstream and downstream sides of the mass flow controller 104 are provided at the line 102. Although not illustrated, in order to perform various annealing processes (NH₃ annealing process and Ar annealing process) for experiments to be described later, the line 102 may be branched into a multiple number of lines. Each of the multiple number of lines may be connected to an NH₃ gas supply source or an Ar gas supply source, and a mass flow controller and valves positioned at upstream and downstream sides of the mass flow controller may be provided at the each line.

An exhaust line 106 is connected to a bottom portion of the chamber 91, and an exhaust device 107 having a vacuum pump or a pressure control valve is connected to the exhaust line 106. By operating the exhaust device 107, the inside of the chamber 91 can be depressurized in a certain pressure level. A loading/unloading port 108 and a gate valve G are provided at a sidewall of the chamber 91. The wafer W is transferred between the transfer chamber 5 and the chamber 91 through the loading/unloading port 108. The gate valve G is configured to open and close the loading/unloading port 108.

In the above-described silicide film forming apparatus, the wafer W having thereon the silicon part is taken out from the carrier C by the transfer device 16 of the loading/unloading chamber 8 and transferred to any one of the load-lock chambers 6 and 7. Subsequently, the load-lock chamber, to which the wafer W has been transferred, is vacuum-evacuated. Thereafter, the wafer W is taken out by the transfer device 12 of the transfer chamber 5 and transferred to the film forming unit 1 to form the CVD-Ni film on the wafer W by using the N-containing Ni compound as the film forming source material. Then, the wafer W, on which the Ni film has been formed, is transferred to the annealing processing unit 2 by the transfer device 12. The annealing process is performed in the annealing processing unit 2 under the hydrogen atmosphere. As a result, the nickel silicide (NiSi) film is formed on the silicon part of the surface of the wafer W. After the nickel silicide film is formed, the wafer W is taken out from the annealing processing unit 2 by the transfer device 12 and transferred to any one of the load-lock chambers 6 and 7. The inside of the load-lock chamber, to which the wafer W has been transferred, is changed to the atmospheric atmosphere. Thereafter, the wafer W is taken out by the transfer device 16 and accommodated in the carrier C.

In order to perform the film forming process in the film forming unit 1, after the gate valve G is opened, the wafer W having thereon the silicon part is transferred into the chamber 31 through the loading/unloading port 55 by the transfer device 12. The wafer W is mounted on the susceptor 32. Subsequently, the susceptor 32 is heated to a certain temperature ranging, e.g., from about 120° C. to about 280° C. by the heater 35. The inside of the chamber 31 is exhausted by the exhaust device 53 such that an internal pressure of the chamber 31 is in a range of from about 40 Pa to about 1330 Pa (about 0.3 Torr to about 10 Torr). In this state, the Ar gas as the bubbling gas is supplied to the N-containing Ni compound as the film forming source material stored in the film forming source material tank 61. Here, the N-containing Ni compound may be, e.g., the nickel amidinate such as the Ni(II)N, N′-ditertiary butylamidinate (Ni(II)(tBu-AMD)₂). The Ni compound as the film forming source material is vaporized by the bubbling gas, and the vaporized film forming source gas is supplied into the chamber 31 through the source gas discharge line 66, the first inlet 41 and the shower head 40. The NH₃ gas as the reduction gas is supplied from the NH₃ gas supply source 72 into the chamber 31 through the branch line 70a, the reduction gas supply line 70, the second inlet 42 and the shower head 40. As the reduction gas, in addition to the NH₃ gas, the H₂ gas may be supplied from the H₂ gas supply source 73 to the reduction gas supply line 70 through the branch line 70b.

In this way, by supplying the Ni compound gas and the reduction gas into the chamber 31, the Ni compound gas reacts with the reduction gas on the surface of the wafer W heated by the susceptor 32. Accordingly, the Ni film is formed on the wafer W by the thermal CVD process. In this case, if necessary, the high frequency power may be applied from the high frequency power supply 59 to the electrode 57 within the susceptor 32 in order to form the Ni film by the plasma CVD process.

Here, desirably, a flow rate of the Ar gas may be set to be in a range of from about 50 mL/min (sccm) to about 500 mL/min (sccm). Further, desirably, a flow rate of the reduction gas (an NH₃ gas or a gas mixture of an NH₃ gas and a H₂ gas) may be set to be in a range of from about 200 mL/min to about 4700 mL/min.

After forming the Ni film, the Ar gas is supplied to the by-pass line 78 without being supplied to the source material tank, so that the inside of the chamber 31 is purged. Thereafter, the gate valve G is opened, and the wafer W, on which the Ni film has been formed, is unloaded by the transfer device 12 through the loading/unloading port 55.

In order to perform the annealing process in the annealing processing unit 2, after opening the gate valve, the wafer W, on which the Ni film has been formed, is loaded into the chamber 91 through the loading/unloading port 108 by the transfer device 12. The wafer W is mounted on the susceptor 92. Subsequently, the inside of the chamber 91 is exhausted by the exhaust device 107 such that an internal pressure of the chamber 91 is set to be in a range of from about 133 Pa to about 665 Pa (about 1 Torr to about 5 Torr). The H₂ gas is introduced from the H₂ gas supply source 103 into the chamber 91 through the line 102 and the gas inlet 101, and the inside of the chamber 91 is changed to the H₂ gas atmosphere. In this state, the susceptor 92 is heated by the heater 95 to a certain temperature ranging, desirably, from about 450° C. to about 550° C., and the annealing process is performed on the wafer W. By the annealing process under the H₂ gas atmosphere, the silicon part of the surface of the wafer W and the Ni film formed thereon react with each other, so that the nickel silicide (NiSi) film can be formed.

In the illustrative embodiment, since the N-containing Ni compound such as the nickel amidinate is used as the film forming source material, the N remains in the Ni film in a deposition state. As a result, nickel nitride (NiₓN) is formed in the film. Further, impurities such as O (oxygen) also remain in the Ni film. In this state, even if the annealing process is performed under the inert gas atmosphere as in a conventional case, it takes some time to remove the N or other impurities from the film by disconnecting the bond between the Ni and the N of the nickel nitride formed in the film. Accordingly, counter diffusion (reaction) between the Ni and the Si is deteriorated, so that generation of the nickel silicide (NiSi) is remarkably delayed.

If the annealing process is performed under the hydrogen atmosphere as in the illustrative embodiment, hydrogen introduced into the Ni film has an atom shape. The atom-shaped hydrogen has a function of rapidly removing the N or the impurities from the Ni film. Accordingly, even when the Ni film including the nickel nitride (NiₓN) or other impurities is formed by using the N-containing Ni compound as the film forming source material, by performing the annealing process under the hydrogen atmosphere after forming the Ni film, the N or the impurities in the Ni film can be rapidly removed. Further, the reaction between the Si in the silicon part of the wafer and the Ni in the Ni film formed thereon can be accelerated. Accordingly, the nickel silicide (NiSi) can be rapidly generated. Furthermore, since the H₂ annealing process is performed in-situ while maintaining the vacuum state after forming the Ni film, the impurities such as O (oxygen) in the film can be further reduced.

Hereinafter, there will be described experiment results which show the background that the present inventors have come to reach the illustrative embodiment and the effects of the illustrative embodiment.

A wafer (SiO₂ wafer) obtained by forming a th-SiO₂ film (thermal oxide film) of about 100 nm on a silicon substrate of about 300 mm and a wafer (Si wafer) obtained by cleaning a surface of the silicon substrate by a dilute hydrofluoric acid are prepared. First, a Ni film is formed on the SiO₂ wafer by the film forming unit illustrated in FIG. 2. In the Ni film forming process, Ni(II)N, N′-ditertiary butylamidinate (Ni(II) (tBu-AMD)₂) is used as a film forming source material, and an NH₃ gas is used as a reduction gas. The Ni(II)N, N′-ditertiary butylamidinate (Ni(II) (tBu-AMD)₂) as the film forming source material is supplied into the chamber 31 under the following fixed conditions: the film forming source material is stored in the film forming source material tank 61; a temperature of the film forming source material is maintained at about 95° C. by the heater 61a; and an Ar gas as a bubbling gas is supplied at about 100 mL/min (sccm). Under such conditions, the Ni film is formed while varying a flow rate of the NH₃ gas from the NH₃ gas supply source 72, a film forming temperature, and a film forming time. These variable conditions are as follows: an NH₃ gas flow rate of about 1100 mL/min (sccm), a wafer temperature of about 200° C., and a film forming time of about 150 sec; an NH₃ gas flow rate of about 1100 mL/min (sccm), a wafer temperature of about 160° C., and a film forming time of about 180 sec; and an NH₃ gas flow rate of about 400 mL/min (sccm), a wafer temperature of about 160° C., and a film forming time of about 300 sec. An internal pressure of the chamber 31 is about 665 Pa (about 5 Torr) in all the cases.

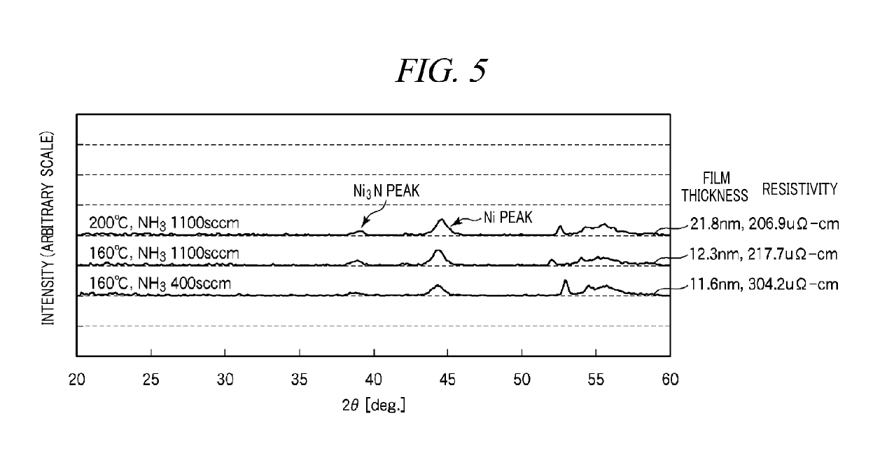

FIG. 5 shows an X-ray diffraction (XRD) measurement result, a film thickness and resistivity of the Ni film formed on the SiO₂ wafer under each condition. In FIG. 5, a vertical axis indicates intensity of a diffracted ray in an arbitrary unit (a.u.), and a horizontal axis indicates an angle of the diffracted ray. In FIG. 5, the graphs are spaced apart from one another in the vertical direction in order not separately show them. As can be seen from the XRD chart of FIG. 5, it can be seen that a peak of Ni₃N appears in addition to a peak of Ni. Further, it can be seen that nickel nitride is generated in the Ni film, i.e., a pure Ni film is not formed.

Subsequently, a Ni film is formed on the SiO₂ wafer and the Si wafer under the same conditions as described above, except for a NH₃ gas flow rate of about 400 mL/min (sccm), a wafer temperature of about 160° C., and a film forming time of about 600 sec. Thereafter, the annealing process is performed on the wafers. As an annealing gas, an NH₃ gas (NH₃ annealing process) and a H₂ gas (H₂ annealing process) are used, respectively. The annealing process is respectively performed at three annealing temperatures of about 450° C., about 500° C. and about 550° C. A gas flow rate is set to be about 3000 mL/min (sccm), an internal pressure of the chamber is set to be about 400 Pa (about 3 Torr), and an annealing time is set to be about 180 sec.

After the annealing process, a crystal analysis is performed by the X-ray diffraction (XRD). Further, sheet resistance of the film after the annealing process is also measured. For comparison, X-ray diffraction (XRD) and sheet resistance of the film in the deposition state.

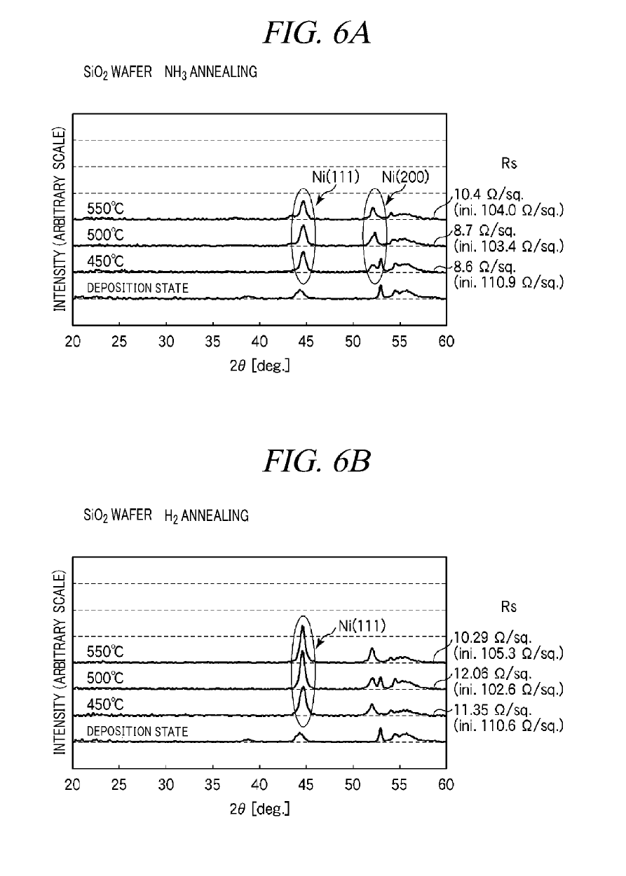

FIGS. 6A and 6B show measurement results of the SiO₂ wafer. FIG. 6A shows when the NH₃ annealing process is performed. FIG. 6B shows when the H₂ annealing process is performed. As shown in these drawings, in case of the Ni film formed on the SiO₂ wafer, no silicide is formed by the annealing process. However, a peak of the Ni₃N does not appear by the annealing process under all the atmospheres. By performing the annealing process, a peak of the Ni is increased under all the atmospheres and at all the temperatures, compared to the film in the deposition state. However, the peak of the Ni after the H₂ annealing process is higher than the peak of Ni after the NH₃ annealing process. It is deemed that the H₂ annealing process has a remarkable effect in removing impurities.

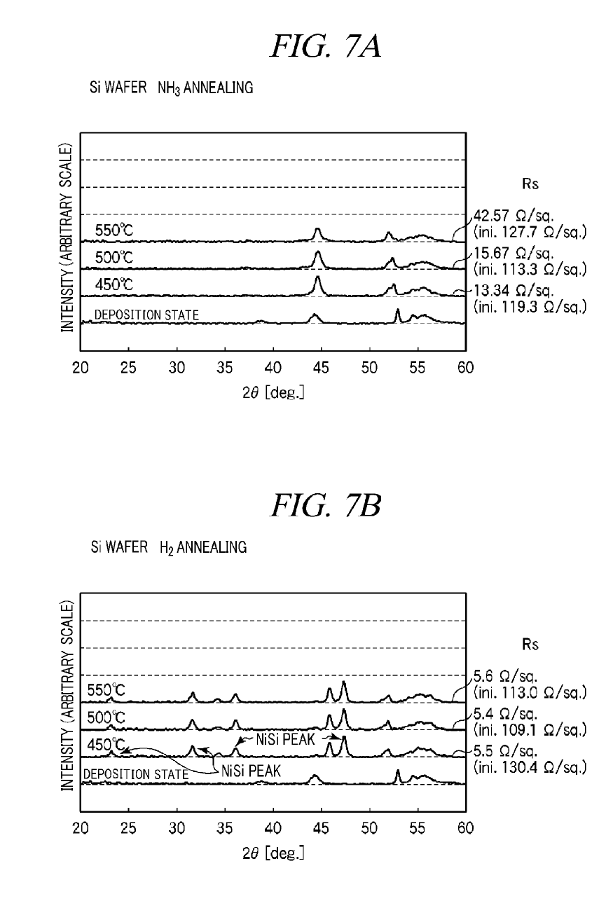

FIGS. 7A and 7B show measurement results for the Si wafer. FIG. 7A shows when the NH₃ annealing process is performed. FIG. 7B shows when the H₂ annealing process is performed. As shown in these drawings, it can be seen that no peak of a nickel silicide (NiSi) appears after the NH₃ annealing process, whereas a peak of a nickel silicide (NiSi) appears after the H₂ gas annealing process. A magnitude of the peak of the nickel silicide (NiSi) is almost constant regardless of varying the annealing temperature from about 450° C. to about 500° C. and to about 550° C. Further, it can be seen that the sheet resistance is remarkably lowered by the H₂ annealing process.

From the above, although both the NH₃ gas and the H₂ gas are used as the reduction gas supplied during the annealing process, the H₂ gas exhibits a higher effect in removing impurities than that of the NH₃ gas. As a result, it is deemed that generation of the nickel silicide (NiSi) is delayed after the NH₃ annealing process, whereas the nickel silicide (NiSi) having low resistance is rapidly formed by the H₂ annealing process.

Subsequently, a Ni film is formed on the Si wafer by supplying the Ni(II) (tBu-AMD)₂) as the film forming source gas under the above-described condition and supplying the NH₃ gas as the reduction gas of about 400 mL/min (sccm). In this case, an internal pressure of the chamber is set to be about 665 Pa (about 5 Torr). A wafer temperature is set to be about 160° C. A target film thickness is set to be about nm. Thereafter, the annealing process is performed on the wafer. As the annealing gas, an Ar gas (Ar annealing process), an NH₃ gas (NH₃ annealing process) and a H₂ gas (H₂ annealing process) are used, respectively. The annealing process is respectively performed at three temperatures of about 450° C., about 500° C., and about 550° C. A gas flow rate is set to be about 3000 mL/min (sccm), an internal pressure of the chamber is set to be about 400 Pa (about 3 Torr), and an annealing time is set to be about 180 sec.

After the annealing process, a crystal analysis is performed by the X-ray diffraction (XRD). Scanning electron microscope (SEM) photographs of the cross section and the surface of the film are taken in order to observe the state thereof. Resistivity and sheet resistance of the film after the annealing process are also measured. For comparison, a crystal analysis of the film in the deposition state by the X-ray diffraction, observation of the state of the cross section and the surface and measurement of resistivity and sheet resistance are performed.

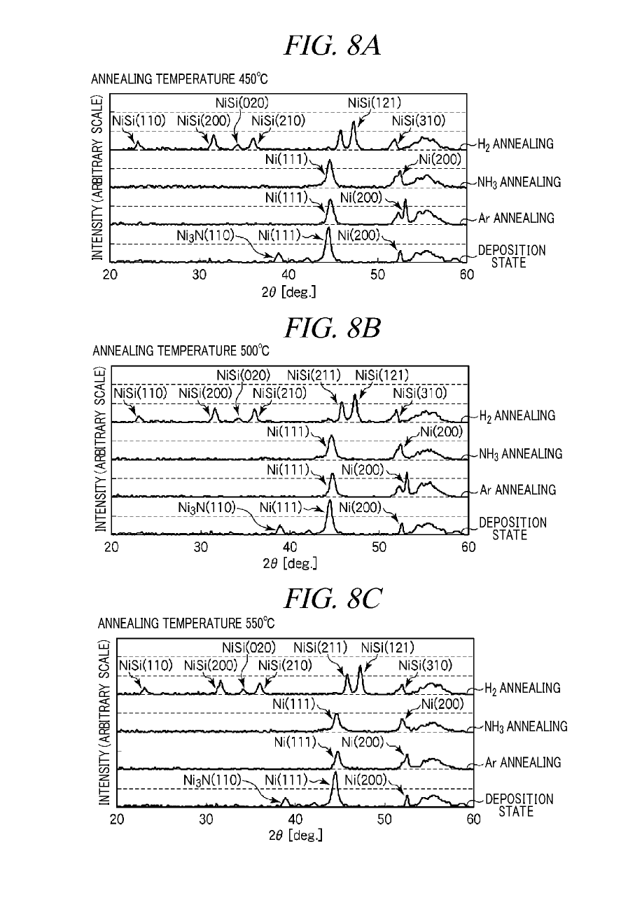

FIGS. 8A to 8C show X-ray diffraction (XRD) measurement results after each annealing process. FIG. 8A shows when the annealing temperature is set to be about 450° C. FIG. 8B shows when the annealing temperature is set to be about 500° C. FIG. 8C shows when the annealing temperature is set to be about 550° C. As shown in these drawings, the nickel silicide (NiSi) is formed only by the H₂ annealing process at all the temperatures. No nickel silicide (NiSi) is formed by the Ar annealing process and the NH₃ annealing process.

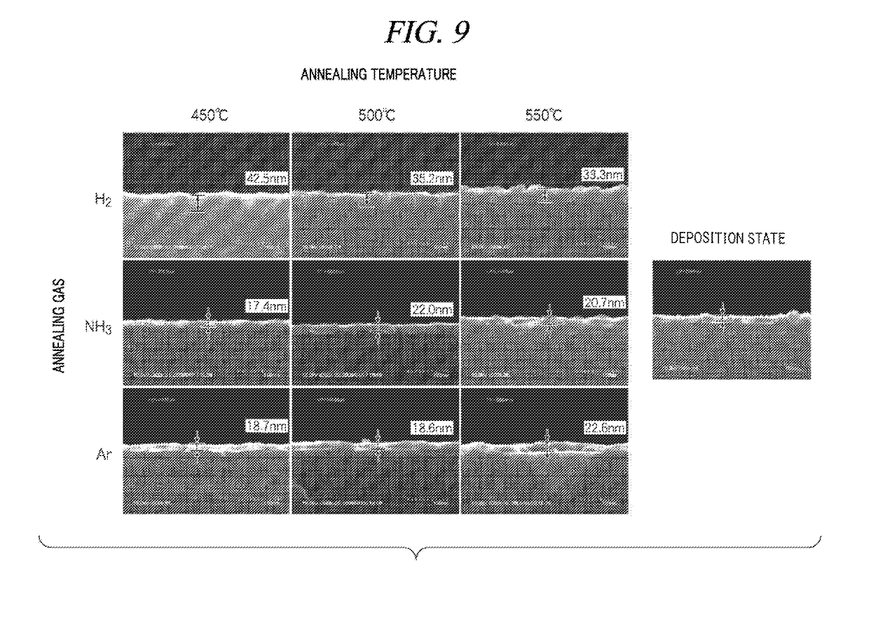

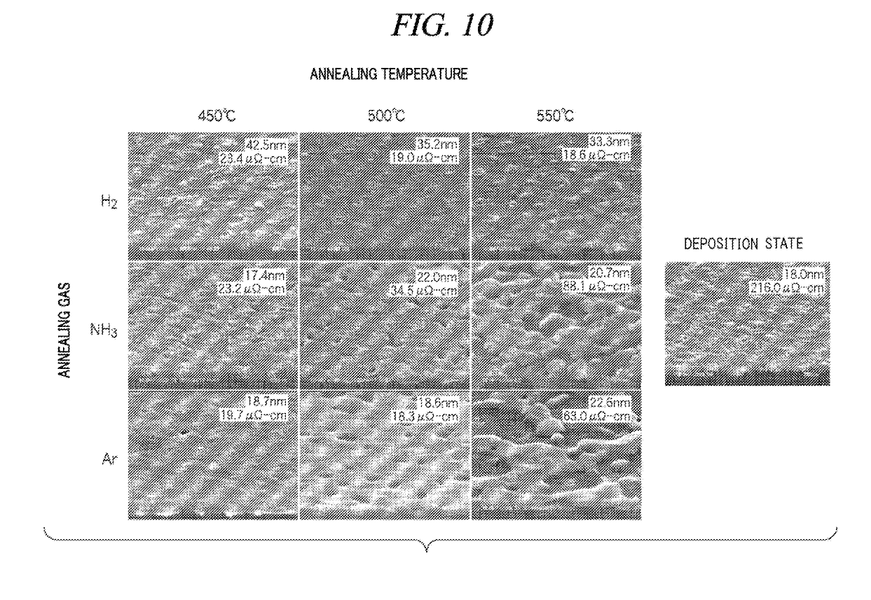

FIGS. 9 and 10 show SEM photographs of the cross section and SEM photographs of the surface in each annealing gas and at each annealing temperature. From the SEM photographs of the cross section in FIG. 9, it can be seen that a film thickness is increased only after the H₂ annealing process at all the temperatures. In the Ar annealing process at about 550° C., a triangle crystal that is expected to be disilicide can be seen. From the SEM photographs of the surface in FIG. 10, it can be seen that after the H₂ annealing process, the surface has a good status at all the temperatures. However, after the NH₃ annealing process and the Ar annealing process, agglomeration of the Ni film occurs on the surface and the degree of the agglomeration becomes severe as the temperature increases. Further, at about 550° C., regions where no Ni film exists appear.

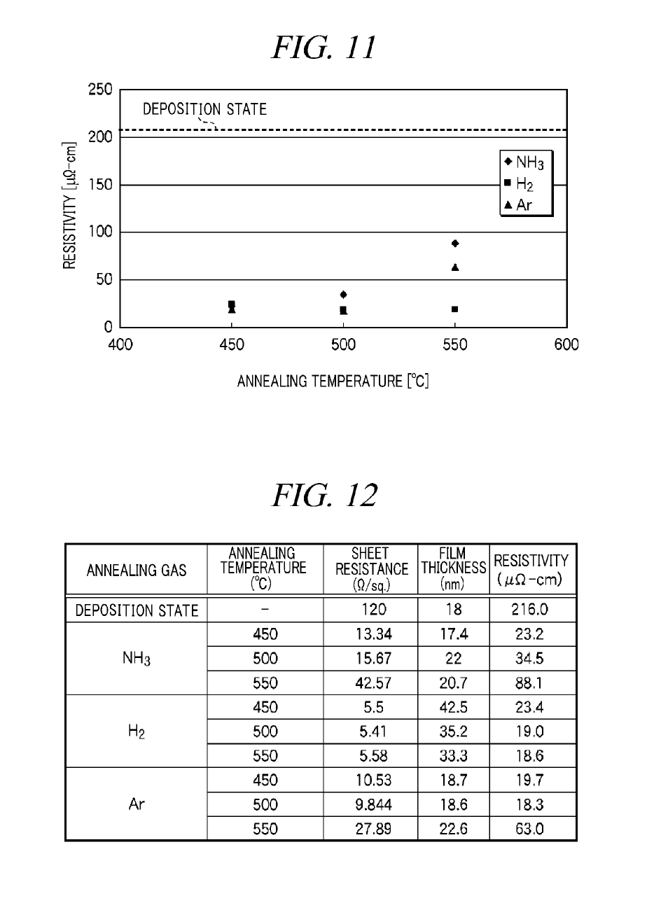

FIG. 11 shows a relationship between an annealing temperature and resistivity of a film formed after the H₂ annealing process, the NH₃ annealing process and the Ar annealing process. As shown in FIG. 11, nickel silicide is stably formed by the H₂ annealing process at all the temperatures. Accordingly, resistivity is stably maintained low regardless of the temperature. Meanwhile, after performing the NH₃ annealing process and the Ar annealing process, the resistivity is lower than that of the film in the deposition state, but rapidly is increased as the annealing temperature increases. It is deemed that the resistivity is increased by the agglomeration of the Ni film as described above.

FIG. 12 shows a table for an annealing gas, an annealing temperature, a sheet resistance value, and a film thickness and resistivity obtained from the SEM photographs. In the H₂ annealing process, a resistance value is low, and a film thickness is increased. From the table shown in FIG. 12, it can be seen that nickel silicide (NiSi) is formed by the H₂ annealing process.

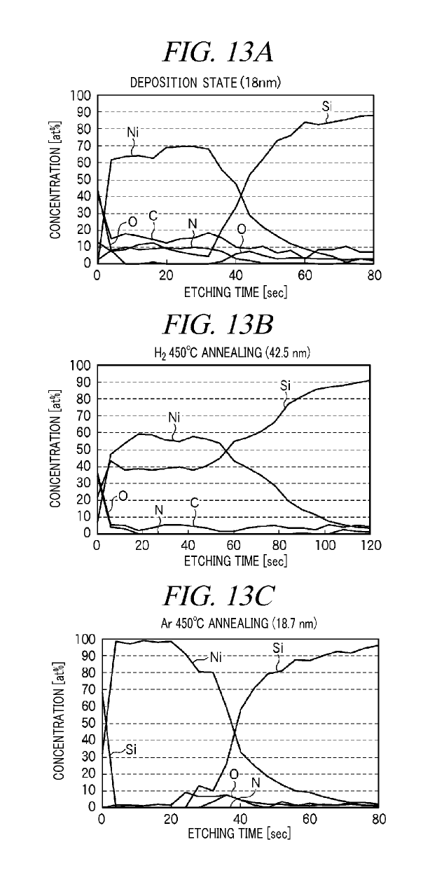

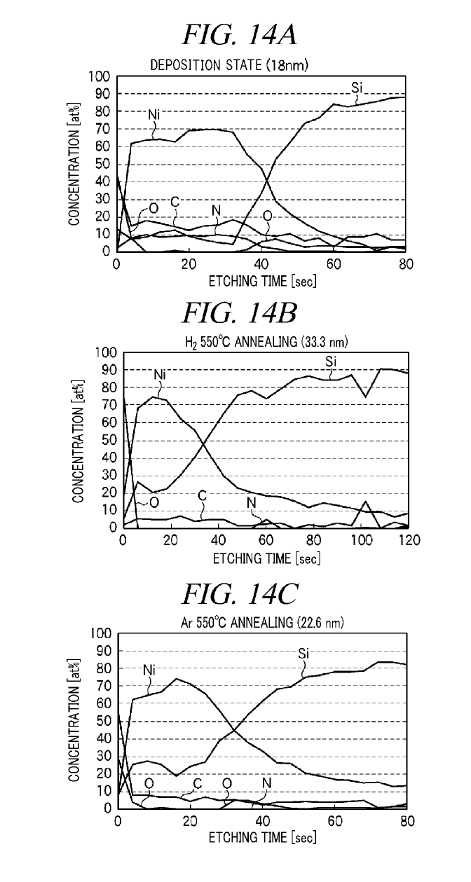

Subsequently, composition of the film and impurities in the film in the deposition state, after the H₂ annealing process (about 450° C. and about 550° C.) and the Ar annealing process (about 450° C. and about 550° C.) are analyzed by the X-ray photoelectron spectroscopy (XPS). During each of the annealing processes, a gas flow rate is set to be about 3000 mL/min (sccm), an internal pressure of the chamber is set to be about 400 Pa (about 3 Torr), and an annealing time is set to be about 180 sec. FIGS. 13A to 13C and 14A to 14C show the XPS analysis results. FIG. 13A shows the XPS analysis result of the Ni film in the deposition state. FIG. 13B shows the XPS analysis result of the Ni film after the H₂ annealing process at about 450° C. FIG. 13C shows the XPS analysis result of the Ni film after the Ar annealing process at about 450° C. FIG. 14A shows the XPS analysis result of the Ni film in the deposition state. FIG. 14B shows the XPS analysis result of the Ni film after the H₂ annealing process at about 550° C. FIG. 14C shows the XPS analysis result of the Ni film after the Ar annealing process at about 550° C.

First, in the Ni film in the deposition state, about 10% of N remains in the Ni film, and a large amount of O (oxygen) exist on the surface of the Ni film. In the film after the H₂ annealing process, the nickel silicide (NiSi) film is formed at both about 450° C. and about 550° C. The N remaining in the film is less than a detection limit (little N exists). No 0 exists in the Ni—Si interface. The film after the Ar annealing process at about 450° C. is still the Ni film, and no nickel silicide (NiSi) film is formed. The N remaining in the film is less than a detection limit, but the 0 remains on the Ni—Si interface. In the film after the Ar annealing process at about 550° C., Si of the substrate is exposed due to the agglomeration of Ni. Thus, the Si appears to be introduced into the Ni film. However, no nickel silicide (NiSi) is formed. Further, the N remaining in the film is less than a detection limit, but the 0 remains on the Ni—Si interface, as in the case of about 450° C.

From the above, when performing the Ar annealing process, the N and other impurities in the film can be somewhat removed, but are not sufficiently removed. Thus, it takes some time to completely remove the N or the 0 as impurities. Accordingly, silicidation of the Ni film is delayed, and silicidation is failed in the process for about 180 sec. However, when performing the H₂ annealing process, the N or the 0 as impurities is rapidly removed, so that silicidation is accomplished in a short time.

The present disclosure is not limited to the above-described illustrative embodiment. The illustrative embodiment can be variously modified. For example, in the above-described illustrative embodiment, although the Ni(II)(tBu-AMD)₂ is described as an example of the N-containing Ni compound as the film forming source material, the illustrative embodiment is not limited thereto. By way of example, the N-containing Ni compound may be other nickel amidinate, an N-containing Ni compound other than nickel amidinate, or an N-containing Ni organic metal compound.

The illustrative embodiment can also be applied to a case where a metal silicide is formed by using nitrogen-containing metal compounds, which include other metal, such as titan (Ti) or cobalt (Co) used for a salicide process, e.g., amidinate.

The illustrative embodiment may be applied to a method for reducing nitrogen in a film during a metal film forming process by using nitrogen-containing metal compounds, which include other metal, such as cupper (Cu), ruthenium (Ru) or tantal (Ta) used for wiring and a barrier, e.g., amidinate.

In the above-described illustrative embodiment, there has been described a multi chamber type silicide forming apparatus having the Ni film forming unit and the annealing processing unit capable of consecutively performing film forming process in-situ while maintaining a vacuum state. However, the illustrative embodiment is not limited thereto. The Ni film forming process and the annealing process may be performed in-situ in the same chamber. In addition, the illustrative embodiment is not limited thereto. The Ni film forming unit and the annealing processing unit may be provided separately, and the annealing process and the Ni film forming process may be performed ex-situ.

The configurations of the film forming unit and the annealing processing unit are not limited to the above-described illustrative embodiment. The method for supplying the N-containing metal compound as the film forming source material may not be limited to the above-described illustrative embodiment. Various methods may be applied to the illustrative embodiment.

The semiconductor wafer is used as the target substrate. However, the present disclosure is not limited thereto. Other substrates such as a flat panel display (FPD) substrate may be used.

What is claimed is:

1. A metal silicide film forming method comprising:
providing a substrate having thereon a silicon part;
forming a metal film on a surface of the silicon part of the substrate by a CVD process using a nitrogen-containing metal compound as a film forming source material, the metal film being composed of a metal contained in the nitrogen-containing metal compound;
performing an annealing process on the substrate under a hydrogen gas atmosphere; and
forming a metal silicide by a reaction between the metal film and the silicon part,
wherein the nitrogen-containing metal compound as the film forming source material is metal amidinate,
the metal film is a nickel (Ni) film, and
the metal amidinate is nickel amidinate.

2. The metal silicide film forming method of claim 1,
wherein the Ni film is formed at a substrate temperature ranging from about 120° C. to about 280° C.

3. The metal silicide film forming method of claim 1,
wherein the annealing process under the hydrogen gas atmosphere is performed at a substrate temperature ranging from about 450° C. to about 550° C.

4. The metal silicide film forming method of claim 1,
wherein forming a metal film and performing an annealing process under the hydrogen gas atmosphere are carried out in-situ while maintaining a vacuum state.

5. The metal silicide film forming method of claim 1,
wherein the silicon part of the substrate is a silicon substrate or a polysilicon film.

6. A storage medium having stored thereon computer-executable instructions that, in response to execution, cause a metal silicide film forming apparatus to perform a metal silicide film forming method,
the metal silicide film forming method including:
providing a substrate having thereon a silicon part;
forming a metal film on a surface of the silicon part of the substrate by a CVD process using a nitrogen-containing metal compound as a film forming source material, the metal film being composed of a metal contained in the nitrogen-containing metal compound;
performing an annealing process on the substrate under a hydrogen gas atmosphere; and
forming a metal silicide by a reaction between the metal film and the silicon part,
wherein the nitrogen-containing metal compound as the film forming source material is metal amidinate,
the metal film is a nickel (Ni) film, and
the metal amidinate is nickel amidinate.
